(19) United States
(12) Patent Application Publication
(10) Pub. No.: US 2026/0052853 A1
(43) Pub. Date: Feb. 19, 2026

(54) DISPLAY DEVICE AND FABRICATION METHOD THEREOF

(71) Applicant: SAMSUNG DISPLAY CO., LTD., YONGIN-SI (KR)

(72) Inventors: JAEHWAN CHU, Yongin-si (KR); EUNHYE KO, Yongin-si (KR); YOUNGOO KIM, Yongin-si (KR); KYOUNG SEOK SON, Yongin-si (KR); SEUNGHUN LEE, Yongin-si (KR)

(21) Appl. No.: 19/083,975

(22) Filed: Mar. 19, 2025

(30) Foreign Application Priority Data
Aug. 13, 2024 (KR) 10-2024-0108418

(51) Int. Cl. H10K 59/124; H10K 59/121

(52) U.S. Cl. CPC H10K 59/124; H10K 59/1213

(57) ABSTRACT

A display device includes a substrate, a light-emitting element layer, and a circuit element layer with a first and second regions that each correspond to a switching transistor and a driving transistor. The circuit element layer includes a semiconductor layer; a first conductive layer, a first insulating layer disposed between the semiconductor layer and the first conductive layer, a second insulating layer, a second conductive layer disposed on the second insulating layer and is in contact with the semiconductor layer by penetrating the first and second insulating layers, and a hydrogen diffusion control layer disposed between the first and second insulating layer and overlapping the second region. The second active pattern comprises a first and a second portion. The hydrogen diffusion control layer covers the first portion of the second active pattern and at least a portion of the second portion does not overlap the hydrogen diffusion control layer.

### CROSS-REFERENCE TO RELATED APPLICATIONS

This application claims priority under 35 U.S.C. § 119 to Korean Patent Application No. 10-2024-0108418, filed on Aug. 13, 2024, in the Korean Intellectual Property Office, the content of which is herein incorporated by reference.

TECHNICAL FIELD The present disclosure relates to a display device and a method for fabricating a display device, specifically to a display device that includes pixels driven by a plurality of transistors and a method for fabricating such a display device.

### DISCUSSION OF THE RELATED ART

A display device provides information to users by displaying various images on its screen. Such display devices are used in a wide range of portable electronic devices, including tablet PCs, smartphones, PDAs (Personal Digital Assistants), PMPs (Portable Multimedia Players), and gaming consoles. Additionally, they are also utilized in various electronic equipment such as televisions, personal computers, laptop computers, and kiosks. Furthermore, in recent times, display devices are increasingly being integrated into wearable electronic devices, such as glasses, to provide users with visual experience.

As the development of various electronic devices and their functionalities increases, there is a growing demand for high-resolution display technologies. For example, high-resolution displays are important in wearable electronic devices that provide virtual reality (VR) or augmented reality (AR) experiences, as lower-resolution devices result in issues such as 3D motion sickness or a less immersive visual experience. High-resolution display devices incorporate increased pixel density, which in turn requires methods to ensure optimal pixel performance while maintaining high levels of integration.

### SUMMARY

A display device according to an embodiment of the present disclosure may include a substrate; a light-emitting element layer disposed on the substrate and comprising a light-emitting material; and a circuit element layer disposed between the substrate and the light-emitting element layer and having a first region that corresponds to a switching transistor and a second region that corresponds to a driving transistor. The circuit element layer includes a semiconductor layer disposed on the substrate and comprising a first active pattern that overlaps the first region and a second active pattern that overlaps the second region; a first conductive layer disposed on the semiconductor layer and comprising a first gate pattern that overlaps the first region and a second gate pattern that overlaps the second region; a first insulating layer disposed between the semiconductor layer and the first conductive layer; a second insulating layer disposed on the first conductive layer; a second conductive layer disposed on the second insulating layer and is in contact with the semiconductor layer by penetrating the first insulating layer and the second insulating layer; and a hydrogen diffusion control layer disposed between the first insulating layer and the second insulating layer, and overlapping the second region. The second conductive layer comprises a first input pattern and a first output pattern that contacts the first active pattern, and a second input pattern and a second output pattern that contacts the second active pattern. The second active pattern comprises a first portion and a second portion that are spaced apart from each other. The hydrogen diffusion control layer covers the first portion of the second active pattern and at least a portion of the second portion does not overlap the hydrogen diffusion control layer.

A display device according to an embodiment of the present disclosure may include a substrate; a light-emitting element layer disposed on the substrate and comprising a light-emitting material; and a circuit element layer disposed between the substrate and the light-emitting element layer and having a first region that corresponds to a switching transistor and a second region that corresponds to a driving transistor. The circuit element layer includes a semiconductor layer disposed on the substrate and comprising a first active pattern that overlaps the first region and a second active pattern that overlaps the second region; a first conductive layer disposed on the substrate and comprising a first gate pattern that overlaps the first region and a second gate pattern that overlaps the second region; a first insulating layer disposed between the semiconductor layer and the first conductive layer; a second insulating layer disposed on the first conductive layer; a second conductive layer disposed on the second insulating layer and is in contact with the semiconductor layer by penetrating the first insulating layer and the second insulating layer; and a hydrogen diffusion control layer disposed between the first insulating layer and the second insulating layer, overlapping the second active pattern, and includes a pattern that allows the first insulating layer to contact the second insulating layer.

An electronic device according to an embodiment of the present disclosure may include a processor; a memory having stored application programs for execution by the processor; a display device; and a user interface configured to sense user input via touch or cursor select of an icon presented on the display panel, wherein the processor is caused to execute one or more of the stored application programs upon receipt of the user input. The display panel includes a display panel. The display panel includes a substrate; a light-emitting element layer disposed on the substrate and comprising a light-emitting material; and a circuit element layer disposed between the substrate and the light-emitting element layer and having a first region that corresponds to a switching transistor and a second region that corresponds to a driving transistor. The circuit element layer includes a semiconductor layer disposed on the substrate and comprising a first active pattern that overlaps the first region and a second active pattern that overlaps the second region; a first conductive layer disposed on the semiconductor layer and comprising a first gate pattern that overlaps the first region and a second gate pattern that overlaps the second region; a first insulating layer disposed between the semiconductor layer and the first conductive layer; a second insulating layer disposed on the first conductive layer; second conductive layer disposed on the second insulating layer and is in contact with the semiconductor layer by penetrating the first insulating layer and the second insulating layer; and a hydrogen diffusion control layer disposed between the first insulating layer and the second insulating layer, and overlapping the second region. The second conductive layer comprises a first input pattern and a first output pattern that contacts the first active pattern, and a second input pattern and a second output pattern that contacts the second active pattern. The second active pattern comprises a first portion and a second portion that are spaced apart from each other. The hydrogen diffusion control layer covers the first portion of the second active pattern and at least a portion of the second portion does not overlap the hydrogen diffusion control layer.

### BRIEF DESCRIPTION OF THE DRAWINGS

These and/or other features will become apparent and more readily appreciated from the following description of the embodiments, taken in conjunction with the accompanying drawings in which:

FIG. 1 is a plan view schematically illustrating a display device according to an embodiment of the present disclosure;

FIG. 2 is an exemplary equivalent circuit diagram of the pixel of FIG. 1;

FIG. 3 is a timing diagram for explaining the operation of the pixel of FIG. 2;

FIG. 4 is an exemplary cross-sectional view of the pixel shown in FIG. 1;

FIG. 5 is a cross-sectional view for explaining the hydrogen diffusion in the driving transistor of FIG. 4;

FIG. 6 is a graph for explaining the reaction rate of hydrogen according to temperature in relation to the driving transistor of FIG. 5;

FIG. 7 is a cross-sectional view of a circuit element layer according to an embodiment of the present disclosure;

FIG. 8 is an exemplary cross-sectional view of the driving transistor of FIG. 7;

FIG. 9 is an exemplary cross-sectional view of the driving transistor of FIG. 7;

FIG. 10 is an exemplary cross-sectional view of the hydrogen diffusion control layer shown in FIG. 7;

FIG. 11 is a cross-sectional view of a circuit element layer according to an embodiment of the present disclosure;

FIG. 12 is an exemplary cross-sectional view of the driving transistor of FIG. 11;

FIG. 13 is an exemplary cross-sectional view of the driving transistor of FIG. 11;

FIG. 14 is a diagram for explaining the effect of the hydrogen diffusion prevention structure according to an embodiment of the present disclosure;

FIGS. 15A, 15B, 15C, 15D, 15E, 15F, and 15G are diagrams for explaining a method of manufacturing a circuit element layer according to an embodiment of the present disclosure;

FIG. 16 is a cross-sectional view of a circuit element layer according to an embodiment of the present disclosure.

FIG. 17 is a block diagram showing an electronic device according to embodiments of the present disclosure.

FIG. 18 illustrates schematic diagrams of electronic devices according to one or more embodiments.

### DETAILED DESCRIPTION

Hereinafter, embodiments of the present disclosure will be described with reference to the drawings.

In the accompanying drawings, ratios and dimensions of the elements may have been exaggerated for the benefit of effective explanation of the technical features associated with these elements. The term “and/or” shall include the combination of a plurality of listed items or any of the plurality of listed items.

Terms such as “first” and “second” shall be construed as being used for merely distinguishing a characteristic, a number, a step, an operation, a component, a part or any combination thereof. For instance, the first element and the second element may be described as the second element and the first element.

To explain a display device according to an embodiment of the present disclosure, a first direction through a third direction DR1, DR2, DR3 may be defined. The display device may include a display panel, and the display panel may be formed to include pixels on a plane defined by the first direction DR1 and the second direction DR2. The third direction DR3 may be defined as a thickness direction of the display device, and the first direction through the third direction DR1, DR2, DR3 may be orthogonal to each other.

In an embodiment of the present disclosure, a display device may include a hydrogen diffusion control layer disposed between a first insulating layer and a second insulating layer. The hydrogen diffusion control layer may regulate the amount of hydrogen diffuses into a semiconductor layer during the formation of a circuit element layer.

In an embodiment of the present disclosure, the hydrogen diffusion control layer may be patterned. The patterned hydrogen diffusion control layer may overlap the active pattern while allowing the first insulating layer to remain in contact with the second insulating layer. This patterning of the hydrogen diffusion control layer may facilitate the formation of an appropriate passivation layer at the interface between the first insulating layer and the active pattern. As a result, the blemishes may be reduced.

In an embodiment of the present disclosure, the hydrogen diffusion control layer may partially overlap the active pattern. For example, the hydrogen diffusion control layer may overlap the source region of the active pattern but not the drain region. As a result, hydrogen diffusion from the second insulating layer to the first insulating layer in the source region may be prevented, while hydrogen may diffuse to the first insulating layer in the drain region, allowing a certain degree of passivation to form. Since passivation of the drain region may be more effective in reducing defects, particularly in black images, passivating the drain region may help reduce these defects.

In an absence of the hydrogen diffusion control layer, hydrogen from the second insulating layer may diffuse into an active pattern, leading to the formation of a passivation layer at an interface between the first insulating layer and the active pattern. The formation of the passivation layer may increase the threshold voltage of a driving transistor, which in turn reduces a range of driving current generated by the transistor. As a result, the light-emission characteristics may be compromised.

The hydrogen diffusion control layer, covering an entire upper surface of the first insulating layer, may prevent hydrogen diffusion between the second insulating layer and the first insulating layer. As a result, an insufficient amount of passivation layer may form at the interface between the first insulating layer and the active pattern. In most cases, passivation helps reduce blemishes and enhances the reliability of the device by preventing unwanted chemical reactions or degradation, the hydrogen diffusion control layer covering the entire first insulating layer may be problematic.

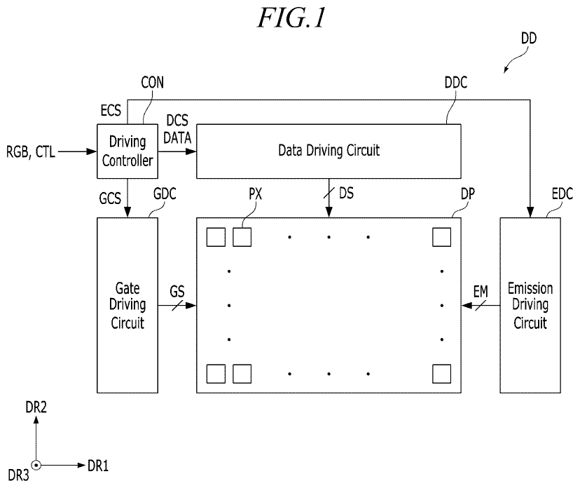

FIG. 1 is a plan view schematically illustrating a display device according to an embodiment of the present disclosure. Referring to FIG. 1, the display device DD includes a display panel DP, a gate driving circuit GDC, an emission driving circuit EDC, a data driving circuit DDC, and a driving controller CON. The display device DD is not necessarily limited to FIG. 1 and may include additional components. For example, the display panel DP may further include a voltage generator or the like for generating the necessary voltages for the components including the display panel DP.

The driving controller CON may receive an image signal RGB and a control signal CTL. In an embodiment of the present disclosure, the image signal RGB and the control signal CTL may be provided from an application processor. The image signal RGB may be construed as a graphic source for an image to be displayed on the display panel DP. The control signal CTL may include a synchronization signal to ensure the image is output at a correct position on the display panel DP. For example, the synchronization signal may include a vertical synchronization signal for distinguishing a frame, a horizontal synchronization signal for distinguishing a row, and a data enable signal for distinguishing an output section of an image data.

The driving controller CON may generate an image data signal DATA by converting a data format of the image signal RGB to match an interface specification of the data driving circuit DDC. The driving controller CON may generate a gate control signal GCS for controlling the gate driving circuit GDC, an emission driving control signal ECS for controlling the emission driving circuit EDC, and a data control signal DCS for controlling the data driving circuit DDC based on the control signal CTL.

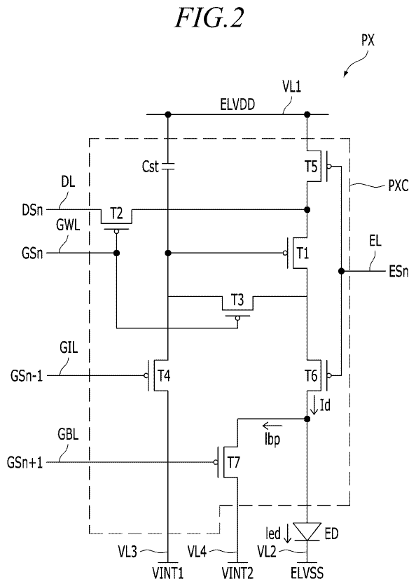

The display panel DP may include pixels PX arranged two-dimensionally on a plane defined by the first direction DR1 and the second direction DR2. The display panel DP may be electrically connected to the gate driving circuit GDC via gate lines GWL, GIL, GBL (See FIG. 2), and may be electrically connected to the emission driving circuit EDC via emission control lines EL (See FIG. 2). The gate lines GWL, GIL, GBL (See FIG. 2) and the emission control lines EL (See FIG. 2) may extend along the first direction DR1. For example, the display panel DP may be disposed between the emission driving circuit EDC and the gate driving circuit GDC. The display panel DP may be electrically connected to the data driving circuit DDC via data lines. The data lines may extend along the second direction DR2.

The data driving circuit DDC may receive the data control signal DCS and the image data signal DATA from the driving controller CON. The data driving circuit DDC may convert the image data signal DATA, which is a digital signal, into analog and transform the image data signal DATA into data signals DS. The data signals DS are converted to corresponding gray scale values of the image data signal DATA. The data driving circuit DDC may output the converted data signal DS to the pixels PX via a plurality of data lines.

The gate driving circuit GDC may receive the gate control signal GCS from the driving controller CON. The gate driving circuit GDC may output the gate signals GS to the gate lines GWL, GIL, GBL (See FIG. 2) based on the gate control signal GCS. The gate driving circuit GDC may perform a sequential activation of a plurality of pixels PX on a row-by-row basis through the gate signals GS. The activation may refer to a state in which data signals DS can be input to the plurality of pixels PX through the data lines.

The emission driving circuit EDC may receive the emission driving control signal ECS from the driving controller CON. The emission driving circuit EDC may output emission control signals EM to the emission control lines EL (See FIG. 2) based on the emission driving control signal ECS. The emission driving circuit EDC may cause the plurality of pixels PX to emit light sequentially on a row-by-row basis based on the emission control signals EM.

FIG. 2 is an exemplary equivalent circuit diagram of the pixel shown in FIG. 1. Referring to FIG. 2, the pixel PX may be electrically connected to a data line DL, gate lines GWL, GIL, GBL (hereinafter referred to as a first gate line GIL, a second gate line GWL, and a third gate line GBL.), and emission control lines EL. The pixel PX may correspond to each of a plurality of pixels PX illustrated in FIG. 1.

The pixel PX may receive a first driving voltage ELVDD, a second driving voltage ELVSS, a first initialization voltage VINT1, and a second initialization voltage VINT2. The first driving voltage ELVDD, the second driving voltage ELVSS, the first initialization voltage VINT1, and the second initialization voltage VINT2 may be provided using voltages generated by a power management circuit or similar components in the display device DD.

The pixel PX may include a pixel circuit PXC and a light-emitting element ED. The pixel circuit PXC may include a first through a seventh transistors T1 to T7 and a capacitor Cst. Each of the first through the seventh transistors T1 to T7 may be a P-type transistor with an LTPS (Low-Temperature Polycrystalline Silicon) semiconductor layer. However, not being necessarily limited to such configurations, the transistors T1 to T7 may also be N-type transistors with an oxide semiconductor as the semiconductor layer. Additionally in an embodiment of the present disclosure, at least one of the first through the seventh transistors T1 to T7 may be an N-type transistor, with the rest being P-type transistors. The circuit configuration of the pixel PX and the number of transistors T1 to T7 according to an embodiment of the present disclosure is exemplary, and shall not be necessarily limited to FIG. 2, and the configuration of the pixel circuit PXC may be modified and implemented.

The first transistor T1 may supply a driving current Id to the light-emitting element ED based on the magnitude of a data signal DSn. In this regard, the first transistor T1 may be referred to as a driving transistor Tdr in FIG. 4 and thereunder. The second to the seventh transistors T2 to T7 may enable the first transistor T1 to receive the data signal DSn and turn on or off to supply the driving current Id based on the magnitude of the data signal DSn. To achieve this, a gate electrode of the second to the seventh transistors T2 to T7 may be connected to at least one of the first gate line GIL, the second gate line GWL, the third gate line GBL or the light-emission control line EL. In this regard, the second to the seventh transistors T2 to T7 may be referred to as a switching transistor Tsw in FIG. 4 and thereunder.

The first transistor T1 may include a first electrode connected to a first driving voltage line VL1 via a fifth transistor T5, a second electrode electrically connected to an anode of the light-emitting element ED via the sixth transistor T6, and a gate electrode connected to one end of the capacitor Cst. The first transistor T1 may receive the data signal DSn transmitted by the data line DL according to a switching operation of the second transistor T2 and supply the driving current Id to the light-emitting element ED.

The second transistor T2 may include a first electrode connected to the data line DL, a second electrode connected to the first electrode of the first transistor T1, and a gate electrode connected to the second gate line GWL. The second transistor T2 may turn on according to a second gate signal GSn received via the second gate line GWL (, and transmit the data signal DSn received from the data line DL to the first electrode of the first transistor T1.

The third transistor T3 may include a first electrode connected to the gate electrode of the first electrode T1, a second electrode connected to the second electrode of the first transistor T1, and a gate electrode connected to the second gate line GWL. The third transistor T3 may be turned on according to the second gate signal GSn received via the second gate line GWL and connect the gate electrode and the second electrode of the first transistor T1 to each other, thereby diode-connecting the first transistor T1.

The fourth transistor T4 may include a first electrode connected to the gate electrode of the first transistor T1, a second electrode connected to a third voltage line VL3 through which the first initialization voltage VINT1 is delivered, and a gate electrode connected to the first gate line GIL. The fourth transistor T4 may be turned on according to a first gate signal GSn-1 received via the first gate line GIL and perform an initialization operation delivering the first initialization voltage VINT1 to the gate electrode of the first transistor T1, thereby initializing the voltage of the gate electrode of the first transistor T1.

The fifth transistor T5 may include a first electrode connected to the first driving voltage line VL1, a second electrode connected to the first electrode of the first transistor T1, and a gate electrode connected to the light-emission control line EL. The sixth transistor T6 may include a first electrode connected to the second electrode of the first transistor T1, a second electrode connected to the anode of the light-emitting element ED, and a gate electrode connected to the light-emission control line EL. The fifth and the sixth transistors T5 and T6 may be turned on simultaneously according to a light-emission control signal ESn received via the light-emission control line EL. The first driving voltage ELVDD, applied through the turned-on fifth transistor T5, may be compensated and delivered to the light-emitting element ED.

The seventh transistor T7 may include a first electrode connected to a fourth voltage line VL4 through which the second initialization voltage VINT2 is delivered, a second electrode connected to the second electrode of the sixth transistor T6, and a gate electrode connected to the third gate line GBL. The seventh transistor T7 may be turned on according to a third gate signal GSn+1 received through the third gate line GBL. The second initialization voltage VINT2, applied through the turned-on seventh transistor T7, may initialize the anode of the light-emitting element ED.

One end of the capacitor Cst may be connected to the gate electrode of the first transistor T1 as previously described, while the other end may be connected to the first driving voltage line VL1. A cathode of the light-emitting element ED may be connected to the second driving voltage line VL2, which delivers the second driving voltage ELVSS.

The light-emitting element ED may include a light-emitting diode. For example, the light-emitting diode may include a light-emitting material such as an organic light-emitting material, an inorganic light-emitting material, a quantum dot, and a quantum rod. The light-emitting element ED may emit light based on a light-emitting current Ied.

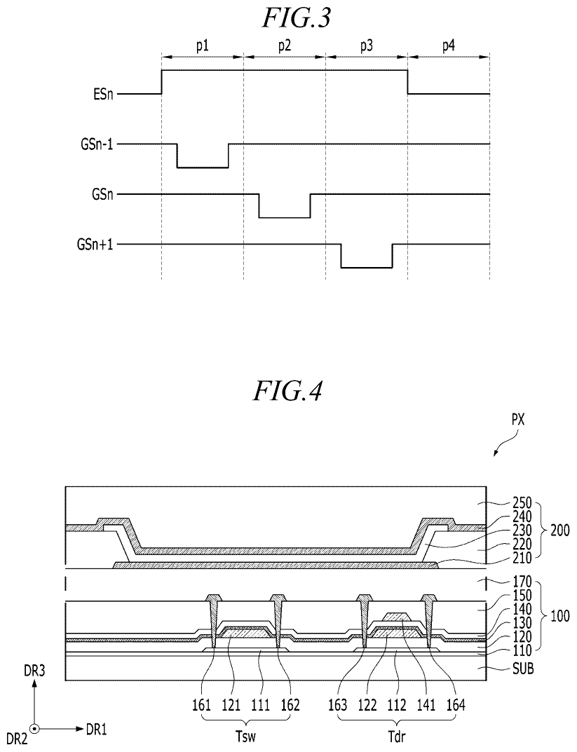

FIG. 3 is a timing diagram that explains an operation of the pixel illustrated in FIG. 2. FIG. 3 will be described with reference to the reference numerals in FIG. 2. Referring to FIG. 3, the pixel PX may operate in four intervals for a light-emission operation: a first interval p1, a second interval p2, a third interval p3, and a fourth interval p4.

In the first interval p1, a node for programming the pixel PX may be initialized. During the first interval p1, a low-level first gate signal GSn−1may be provided through the first gate line GIL. Based on the low-level first gate signal GSn−1, the fourth transistor T4 may be turned on, and through the fourth transistor T4, the first initialization voltage VINT1 may be delivered to the gate electrode of the first transistor T1, enabling the first transistor T1 to be initialized.

In the second interval p2, a pixel PX may be programmed. During the second interval p2, when the low-level first gate signal GSn−1 is supplied through the first gate line GIL, the third transistor T3 may be turned on. The first transistor T1 is diode-connected by the turned-on third transistor T3 and may be forward biased. Additionally, the second transistor T2 may be turned on due to the low-level first gate signal GSn−1. Accordingly, a compensated voltage reduced by a threshold voltage Vth of the first transistor T1, from the data signal DSn supplied from the data line DL, may be applied to the gate electrode of the first transistor T1. Such gate voltage may be construed as a compensated voltage. The first driving voltage ELVDD and the compensated voltage may be applied to both terminals of the capacitor Cst, and charge corresponding to a voltage difference between both terminals may be stored in the capacitor Cst.

In the third interval p3, the anode of the light-emitting element ED may be initialized. The seventh transistor T7 may be turned on by receiving the low-level third gate signal GSn+1 through the third gate line GBL. If a minimum current of the first transistor T1, which displays a black image, flows as a driving current, the light-emitting element ED may still emit light, potentially preventing the black image from being displayed correctly. Therefore, the seventh transistor T7 may redirect part of the minimum current of the first transistor T1 as a bypass current Ibp through a path other than a current path toward an organic light-emitting diode. The light-emitting current Ied of the light-emitting element ED, reduced by the bypass current Ibp from the driving current Id, may have the minimum current needed to properly display the black image, improving the contrast ratio.

In the fourth interval p4, the light-emitting element ED may emit light based on the programmed data signal DSn. The light-emission control signal ESn, supplied from the light-emission control line EL, may change from a high level to a low level. The fifth and the sixth transistors T5 and T6 may be turned on by the low-level light-emission control line EL. As a result, a driving current Id may be generated due to a voltage difference between the gate electrode of the first transistor T1 and the first driving voltage ELVDD. The driving current Id may be supplied to the light-emitting element ED through the sixth transistor T6, enabling the light-emitting current Ied to flow through the light-emitting element ED.

FIG. 4 is an exemplary cross-sectional view of a pixel shown in FIG. 1. Referring to FIG. 4, the pixel PX may include a substrate SUB, a circuit element layer 100, and a light-emitting element layer 200. For the sake of explanation, a cross-sectional view of a pixel PX is depicted; however, as illustrated in FIG. 1, the pixels PX are arranged in a two-dimensional array, and the cross-sectional view of FIG. 4 may be repeatedly arranged along the first direction DR1. The pixels PX may be fabricated simultaneously during the process of forming the circuit element layer 100 and the light-emitting element layer 200, as illustrated in FIG. 4. Furthermore, the cross-sectional view of the pixel PX is simplified for ease of explanation.

The substrate SUB may be formed from various materials such as glass, metal, or plastic. In an embodiment of the present disclosure, the substrate SUB may be a flexible substrate.

The circuit element layer 100 may be disposed on the substrate SUB. The circuit element layer 100 may correspond to the pixel circuit PXC shown in FIG. 2. The circuit element layer 100 may include a buffer layer 110, a semiconductor layer comprising a first active pattern 111 and a second active pattern 112, a first insulating layer 120, a first conductive layer comprising a first gate pattern 121 and a second gate pattern 122, a hydrogen diffusion control layer 130, a second insulating layer 140, a second conductive layer comprising a third gate pattern 141, a third insulating layer 150, a third conductive layer comprising a first input pattern 161, a first output pattern 162, a second input pattern 163 and a second output pattern 164, and a planarization layer 170.

The circuit element layer 100 may form a switching transistor Tsw and a driving transistor Tdr according to the stack structure of FIG. 4. The driving transistor Tdr may correspond to the first transistor T1 of FIG. 2, and the switching transistor Tsw may correspond to any one of the second to the seventh transistors T2 to T7 of FIG. 2. For the sake of explanation, a cross-sectional view in FIG. 4 illustrates one switching transistor Tsw and one driving transistor Tdr, but it shall be construed as exemplary. The number of switching transistors Tsw and driving transistors Tdr illustrated in a cross-section defined by the first direction DR1 and the third direction DR3 is not necessarily limited.

The buffer layer 110 may be positioned on the substrate SUB. The buffer layer 110 may prevent impurity ions from diffusing on the surface of the substrate SUB, block moisture or external air from penetrating, and flatten the surface. According to an embodiment of the present disclosure, the buffer layer 110 may be formed of an inorganic material such as a silicon oxide, a silicon nitride, an aluminum oxide, an aluminum nitride, a titanium oxide, or a titanium nitride, or it may be formed of an organic material such as a polyimide, a polyester, an acrylic, or a stack of these substances.

The semiconductor layer, which includes the first active pattern 111 and the second active pattern 112, may be disposed on the substrate SUB and the buffer layer 110. According to an embodiment of the present inventive concept, the semiconductor layer may use an inorganic semiconductor, such as an amorphous silicon or a polysilicon, or an organic semiconductor. The first active pattern 111 may provide a signal input/output channel for the switching transistor Tsw, and the second active pattern 112 may provide a signal input/output channel for the driving transistor Tdr.

The first insulating layer 120 may be disposed on the semiconductor layer. For example, the first insulating layer 120 may be disposed on the first active pattern 111 and the second active pattern 112, covering the first active pattern 111 and the second active pattern 112. According to an embodiment of the present disclosure, the first insulating layer 120 may be formed as a stack structure comprising a silicon oxide, but is not necessarily limited thereto. The first insulating layer 120 may function as a gate insulator for the switching transistor Tsw and the driving transistor Tdr.

The first conductive layer, including the first gate pattern 121 and the second gate pattern 122, may be disposed on the first insulating layer 120. The first gate pattern 121 may overlap the first active pattern 111, and the second gate pattern 122 may overlap the second active pattern 112. The first gate pattern 121 may serve as a gate electrode of the switching transistor Tsw, and the second gate pattern 122 may serve as a gate electrode of the driving transistor Tdr. The first conductive layer may further include the aforementioned gate lines GWL, GIL, GBL and emission control lines EL. According to an embodiment of the present disclosure, the gate lines GWL, GIL, GBL or emission control lines EL may be electrically connected to the first gate pattern 121 of the corresponding switching transistor Tsw among the second to the seventh transistor T2 to T7 in FIG. 2.

The hydrogen diffusion control layer 130 may be disposed on the first insulating layer 120 and may further be disposed on the first conductive layer. The hydrogen diffusion control layer 130 may control the amount of hydrogen diffused into the semiconductor layer in the process of forming the circuit element layer 100. For example, the driving transistor Tdr may determine the intensity of the driving current Id, which in turn may determine the brightness of the light emitted by the light-emitting element layer 200. However, the performance of the driving transistor Tdr may be sensitive to hydrogen diffusion, which may alter the electrical properties. For example, the hydrogen atoms may alter the carrier mobility or modify the threshold voltage of the driving transistor Tdr. The hydrogen diffusion control layer 130 may control a hydrogen diffusion from the second insulating layer 140 or the third insulating layer 150 into the second active pattern 112.

FIG. 4 illustratively shows the hydrogen diffusion control layer 130 covering the entire upper surface of the first insulating layer 120, though this should be understood as exemplary. Since the switching transistor Tsw is a device for switching signals intended for the light-emission operation, the switching transistor Tsw may not exhibit performance changes sensitive to hydrogen diffusion compared to the driving transistor Tdr. Therefore, the hydrogen diffusion control layer 130 may not cover the area corresponding to the switching transistor Tsw. Additionally, passivation resulting from the hydrogen diffusion may enhance appearance by reducing blemishes, increasing reliability of the device. This is because the passivation layer may stabilize the surface, preventing unwanted chemical reactions or degradation. Thus, the hydrogen diffusion control layer 130 may be patterned to allow a controlled amount of hydrogen diffusion. Specific details regarding this will be described hereafter.

The second insulating layer 140 may be disposed on the first conductive layer, which includes the first gate pattern 121 and the second gate pattern 122, and on the hydrogen diffusion control layer 130, and may cover the first conductive layer and the hydrogen diffusion control layer 130. According to an embodiment of the present disclosure, the second insulating layer 140 may be formed as a stack structure that includes a silicon oxide or a silicon nitride but is not necessarily limited thereto. When the second insulating layer 140 includes a silicon nitride and the first insulating layer 120 includes a silicon oxide, the second insulating layer 140 including the silicon nitride may have a higher hydrogen content than the first insulating layer 120 including the silicon oxide. Having higher hydrogen content may facilitate hydrogen diffusion between the second insulating layer 140 and the first insulating layer 120. The hydrogen diffusion control layer 130 may control appropriate hydrogen diffusion.

The second insulating layer 140 may function as the dielectric of the capacitor Cst described in FIG. 2. The second insulating layer 140 may have a higher hydrogen content than the first insulating layer 120. The second insulating layer 140 may include a silicon nitride and the first insulating layer 120 may include a silicon oxide, which has a lower hydrogen content than the silicon nitride. Since silicon nitride has a higher dielectric constant and superior moisture and ion-blocking capabilities compared to silicon oxide, the second insulating layer 140 may be suitable for use as an interlayer insulating layer or as a capacitor dielectric. In contrast, since silicon oxide has appropriate interfacial characteristics with the silicon substrate and a dielectric constant, the first insulating layer 120 may be appropriate for use as a gate insulating layer. The hydrogen diffusion control layer 130 may control hydrogen diffusion from the second insulating layer 140 to the first insulating layer 120.

The second conductive layer, which includes the third gate pattern 141, may be disposed on the second insulating layer 140. The third gate pattern 141 may be disposed to overlap the second gate pattern 122. The second gate pattern 122 and the third gate pattern 141 may function as the capacitor Cst described in FIG. 2. As the capacitor Cst may overlap a region corresponding to the driving transistor Tdr, the pixel PX may be miniaturized and integrated, potentially increasing the resolution of the display device DD. However, without limitation thereto, the third gate pattern 141 may also be disposed so as not to overlap the region corresponding to the driving transistor Tdr.

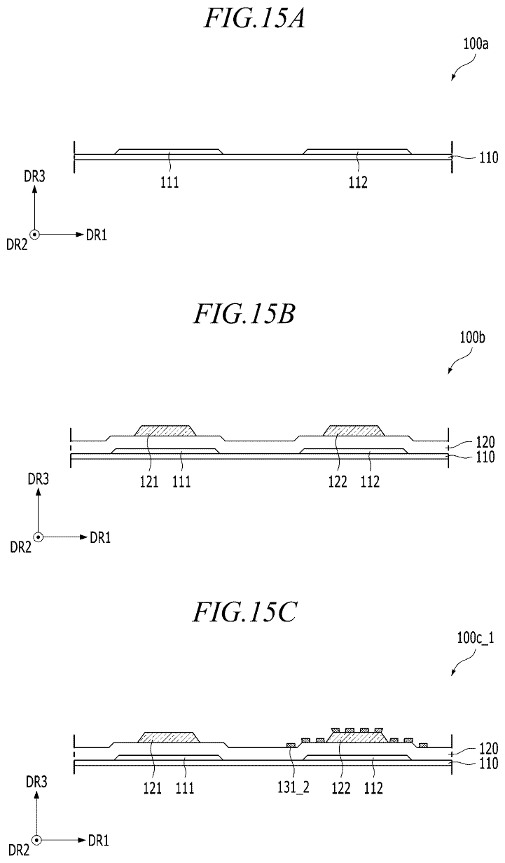

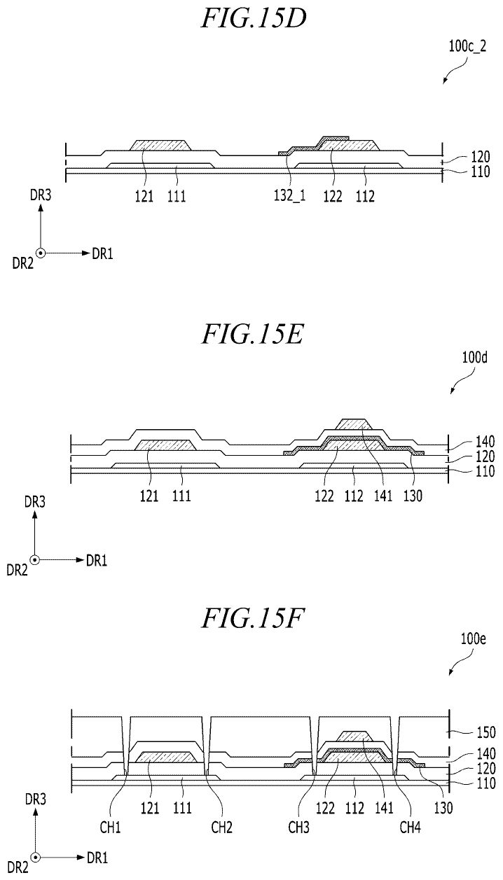

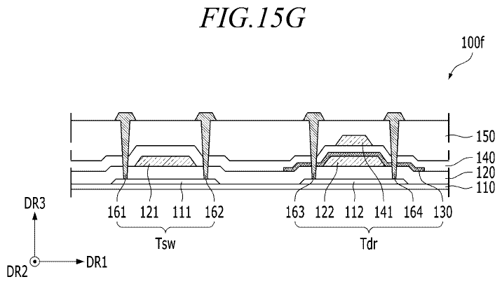

The third insulating layer 150 may be disposed on the second conductive layer, which includes the third gate pattern 141, and may cover the second conductive layer. According to an embodiment of the present disclosure, the third insulating layer 150 may be a stack structure containing a silicon oxide or a silicon nitride, without being necessarily limited thereto. When the third insulating layer 150 contains a silicon nitride and the first insulating layer 120 contains a silicon oxide, the higher hydrogen content in silicon nitride compared to silicon oxide may lead to active hydrogen diffusion, and the hydrogen diffusion control layer 130 may control to ensure appropriate hydrogen diffusion. Contact holes CH1, CH2, CH3, and CH4 (see FIG. 15F) may be formed in the third insulating layer 150 for forming the first input pattern 161, the first output pattern 162, the second input pattern 163, and the second output pattern 164.

The third insulating layer 150 may have a higher hydrogen content than the first insulating layer 120. The third insulating layer 150 may include silicon nitride, and the first insulating layer 120 may include a silicon oxide, which has a lower hydrogen content than a silicon nitride. As described above, since the silicon nitride has a higher dielectric constant than silicon oxide and exhibits superior moisture and ion blocking capabilities, the third insulating layer 150 may be suitable for use as an interlayer insulating layer. The hydrogen diffusion control layer 130 may control hydrogen diffusion from the third insulating layer 150 to the first insulating layer 120.

The third conductive layer, which includes the first input pattern 161, the first output pattern 162, the second input pattern 163, and the second output pattern 164, may be disposed on the third insulating layer 150 and may contact the semiconductor layer through the aforementioned contact holes CH1, CH2, CH3, CH4 in the third insulating layer 150. The first input pattern 161 and the first output pattern 162 may penetrate the first to the third insulating layers 120, 140, 150 and contact the first active pattern 111. The second input pattern 163 and the second output pattern 164 may penetrate the first to the third insulating layers 120, 140, 150 and contact the second active pattern 112. The first input pattern 161 may serve as an input electrode of the switching transistor Tsw, the first output pattern 162 may serve as an output electrode of the switching transistor Tsw, the second input pattern 163 may serve as an input electrode of the driving transistor Tdr, and the second output pattern 164 may serve as an output electrode of the driving transistor Tdr.

The third conductive layer may further include the aforementioned data lines and a driving line. In an embodiment of the present disclosure, the data line may be electrically connected to the first input pattern 161 of the switching transistor Tsw corresponding to the second transistor T2 in FIG. 2. According to another embodiment of the present disclosure, the driving line may be electrically connected to the third gate pattern 141. The driving line may be positioned physically adjacent to the second input pattern 163, which receives the driving current, rather than to the second output pattern 164, which outputs the driving current.

The planarization layer 170 may be disposed below the light-emitting layer 200. The planarization layer 170 may provide a flat upper surface to allow the light-emitting element layer 200 to be formed evenly. The planarization layer 170 may be formed as a single layer or a multilayer film comprised of an organic or an inorganic material. Contact holes CH1, CH2, CH3, CH4 may be formed in the planarization layer 170 to electrically connect to the third conductive layer. Contact patterns formed in the contact holes CH1, CH2, CH3, CH4 may transfer the driving current supplied from the circuit element layer 100 to the light-emitting element layer 200. The contact pattern may be positioned physically adjacent to the second output pattern 164, which outputs the driving current, rather than adjacent to the second input pattern 163, which receives the driving current.

The light-emitting element layer 200 may be disposed on the circuit element layer 100. The light-emitting element layer 200 may correspond to the light-emitting element ED in FIG. 2. The light-emitting element layer 200 may include a first electrode layer 210, a pixel defining layer 220, and light-emitting layer 230, a second electrode layer 240, and an encapsulation layer 250. It shall be construed that a configuration of the light-emitting element layer 200 is simplified for ease of explanation.

The first electrode layer 210 may be disposed on the planarization layer 170. The first electrode layer 210 may include a conductive oxide, such as an indium tin oxide (ITO), an indium zinc oxide (IZO), a zinc oxide (ZnO), an indium oxide (In₂O₃), an indium gallium oxide (IGO), or an aluminum zinc oxide (AZO). The first electrode layer 210 may serve as an anode electrode of the light-emitting element ED.

The pixel defining layer 220 may be disposed on the first electrode layer 210 and the planarization layer 170. An opening may be defined in the pixel defining layer 220, exposing at least a portion of the first electrode layer 210 through the opening. The pixel defining layer 220 may define an area corresponding to a single pixel PX by the opening. The pixel defining layer 220 may define a non-emission area overlapping the pixel defining layer 220 and an emission area exposed by the opening within the display panel DP.

The light-emitting layer 230 may be disposed on the first electrode layer 210 and the pixel defining layer 220. The light-emitting layer 230 may include a light-emitting material. In an embodiment of the present disclosure, the light-emitting layer 230 may include an organic material including a fluorescent or a phosphorescent material that emit light such as red, green and blue. The light-emitting layer 230 may include a low-molecular organic material or a high-molecular organic material. The light-emitting element layer 200 may further include a hole control layer, such as a hole transport layer (HTL) and a hole injection layer (HIL) disposed between the light-emitting layer 230 and the first electrode layer 210. The light-emitting element layer 200 may further include an electron control layer, such as an electron transport layer (ETL) and an electron injection layer (EIL) disposed between the light-emitting layer 230 and the second electrode layer 240.

The second electrode layer 240 may be disposed on the light-emitting layer 230 and the pixel defining layer 220. The second electrode layer 240 may be arranged across the plurality of pixels PX. The second electrode layer 240 may function as a transparent electrode or a reflective electrode. Alternatively, the second electrode layer 240 may be a transparent or semi-transparent electrode. The second electrode layer 240 may include a conductive oxide, such as an indium tin oxide (ITO), an indium zinc oxide (IZO), a zinc oxide (ZnO), an indium oxide (In₂O₃), an indium gallium oxide (IGO), or an aluminum zinc oxide (AZO). The second electrode layer 240 may serve as the cathode electrode of the light-emitting element ED.

The encapsulation layer 250 may be disposed on the second electrode layer 240. The encapsulation layer 250 may include at least one inorganic encapsulation layer and at least one organic encapsulation layer. The encapsulation layer 250 may protect the light-emitting element layer 200 from external moisture or contaminants.

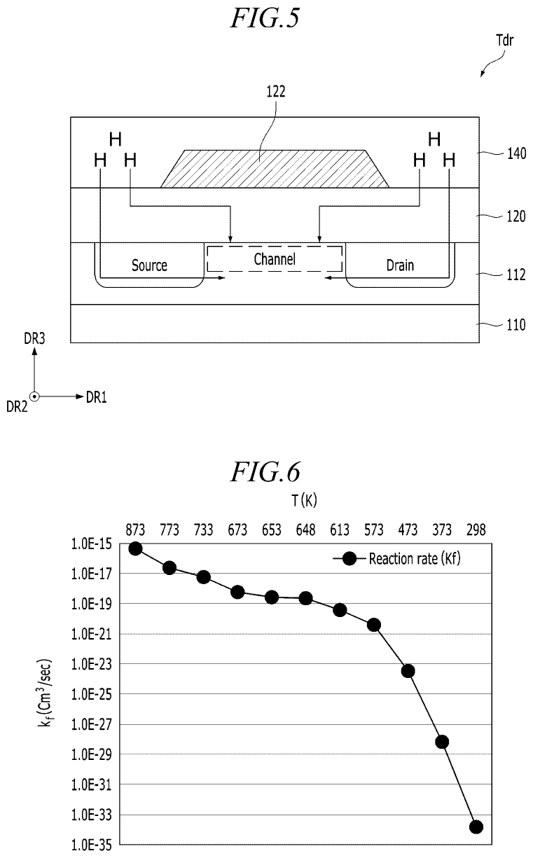

FIG. 5 is a cross-sectional view illustrating hydrogen diffusion in the driving transistor of FIG. 4. FIG. 5 shows hydrogen diffusion when the hydrogen diffusion control layer 130 described in FIG. 4 is not provided. FIG. 6 is a diagram explaining a reaction rate of hydrogen according to temperature in relation to the driving transistor of FIG. 5.

Referring to FIG. 5, the driving transistor Tdr may include the buffer layer 110, the active pattern 112, the first insulating layer 120, the gate pattern 122, and the second insulating layer 140. When the second insulating layer 140 includes a silicon nitride and the first insulating layer 120 includes a silicon oxide, the higher hydrogen content in silicon nitride compared to silicon oxide may promote hydrogen diffusion from the second insulating layer 140 into the first insulating layer 120. Moreover, since silicon oxide is a porous material, hydrogen diffusion may reach the active pattern 112 that is disposed below the first insulating layer 120.

Hydrogen included in the second insulating layer 140 may diffuse into the active pattern 112 through the first insulating layer 120. Hydrogen, which is unable to diffuse into the conductive layer, may bypass the gate pattern 122 and move to the first insulating layer 120. Hydrogen may diffuse into the active pattern 112 through the source region connected to the second input pattern 163 or the drain region connected to the second output pattern 164. Additionally, hydrogen may form passivation layer at the interface between the first insulating layer 120 and the active pattern 112.

Referring to FIG. 6, the horizontal axis represents temperature, and the vertical axis represents the reaction rate of hydrogen. As temperature increases, the reaction rate of hydrogen also increases. Additionally, as miniaturization or integration of the display device DD advances, an internal volume of the driving transistor Tdr may decrease, and a reaction space may be reduced, which may amplify the impact on the device's performance. For example, as the resolution of the display device DD increases, the number of pixels PX per unit area rises, and the distance between the source and drain regions of the driving transistor Tdr may be reduced. As the components become more tightly packed, there may be less room for thermal dissipation. Consequently, the allowable temperature margin of the driving transistor Tdr may decrease.

Referring again to FIG. 5, during the deposition process of the first insulating layer 120 and the second insulating layer 140, heat treatment may be conducted. During the heat treatment, the temperatures of the first insulating layer 120 and the second insulating layer 140 may increase, accelerating the reaction rate of the diffused hydrogen. Excessive passivation formed at an interface between the first insulating layer 120 and the active pattern 112 may raise a threshold voltage of the driving transistor Tdr. Consequently, the range of driving current generated by the driving transistor Tdr may be reduced, which may diminish the light-emission characteristics based on gray scale values.

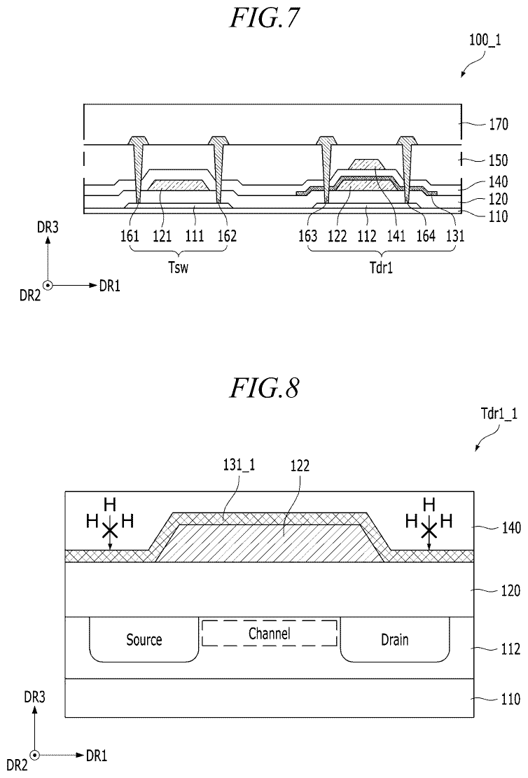

FIG. 7 is a cross-sectional view of a circuit element layer according to an embodiment of the present disclosure. Referring to FIG. 7, the circuit element layer 100_1 may include a buffer layer 110; a semiconductor layer that includes a first active pattern 111 and a second active pattern 112; a first insulating layer 120; a first conductive layer that includes a first gate pattern 121 and a second gate pattern 122; a hydrogen diffusion control layer 131; a second insulating layer 140; a second conductive layer that includes a third gate pattern 141; a third insulating layer 150; a third conductive layer that includes a first input pattern 161, a first output pattern 162, a second input pattern 163, and a second output pattern 164; and a planarization layer 170.

The circuit element layer 100_1 illustrated in FIG. 7 is substantially the same as the circuit element layer 100 shown in FIG. 4, except for the hydrogen diffusion control layer 130. FIG. 7 is described with reference to the hydrogen diffusion control layer 131. The circuit element layer 100_1 may form a switching transistor Tsw and a driving transistor Tdr1. The hydrogen diffusion control layer 131 may overlap with the second active pattern 112 formed on the driving transistor Tdr1 and may not overlap with the first active pattern 111 formed on the switching transistor Tsw. As described above, since the switching transistor Tsw is a component aimed at switching signals for light-emission operations, the switching transistor Tsw may not exhibit performance changes sensitive to hydrogen diffusion compared to the driving transistor Tdr1, which is sensitive to hydrogen diffusion. Therefore, the hydrogen diffusion control layer 131 may not be provided on the switching transistor Tsw.

FIG. 8 is an exemplary cross-sectional view of the driving transistor of FIG. 7. Referring to FIG. 8, a driving transistor Tdr1_1 includes a buffer layer 110, an active pattern 112, a first insulating layer 120, a gate pattern 122, a hydrogen diffusion control layer 131_1, and a second insulating layer 140. Compared to the hydrogen diffusion control layer 130 illustrated in FIG. 4, the hydrogen diffusion control layer 131_1 may prevent hydrogen diffusion from the second insulating layer 140 to the first insulating layer 120.

The hydrogen diffusion control layer 131_1 may include an insulating layer that may prevent the flow of electrical signals supplied to the gate pattern 122 and may include a material that blocks hydrogen movement. According to an embodiment of the present disclosure, the hydrogen diffusion control layer 131_1 may include a graphene layer or a graphene oxide layer.

The hydrogen diffusion control layer 131_1 may be disposed between the first insulating layer 120 and the second insulating layer 140. The hydrogen diffusion control layer 131_1 may be positioned on the active pattern 112 and may cover the active pattern 112. As a result, adequate passivation may not be formed at an interface between the first insulating layer 120 and the active pattern 112. In this case, defects in an oxide semiconductor of the active pattern 112 may not be repaired by hydrogen, as the hydrogen in passivation interacts with and stabilize defects. The driving transistor Tdr1_1 may have reduced reliability. Moreover, blemishes may appear on the display, disrupting the image quality. For example, when displaying black images, where no driving current should flow to the light-emitting element ED, unintended leakage current may occur and may cause flickering.

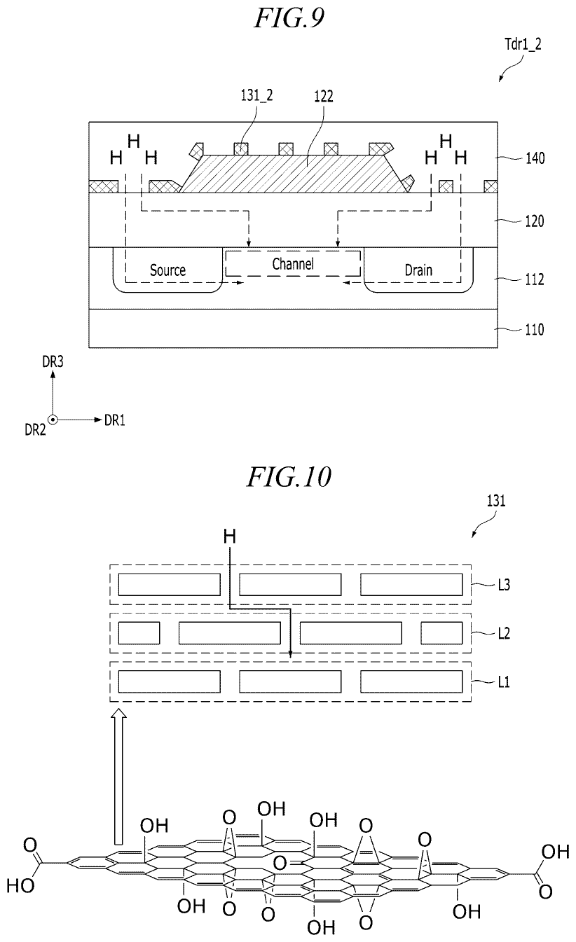

FIG. 9 is an exemplary cross-sectional view of the driving transistor of FIG. 7. Referring to FIG. 9, a driving transistor Tdr1_2 may include a buffer layer 110, an active pattern 112, a first insulating layer 120, a gate pattern 122, a hydrogen diffusion control layer 131_2, and a second insulating layer 140. Compared to the hydrogen diffusion control layer 131_1 illustrated in FIG. 8, the hydrogen diffusion control layer 131_2 may be patterned to allow at least some hydrogen to diffuse from the second insulating layer 140 to the first insulating layer 120.

The hydrogen diffusion control layer 131_2 may overlap the active pattern 112. The hydrogen diffusion control layer 131_2 may provide a pattern for the first insulating layer 120 to be in contact with the second insulating layer 140 disposed on the active pattern 112. In an embodiment of the present disclosure, the hydrogen diffusion control layer 131_2 may be provided in a mesh form and may form a plurality of holes or grooves to provide hydrogen diffusion paths. According to an embodiment of the present disclosure, the hydrogen diffusion control layer 131_2 may include a graphene layer or a graphene oxide layer.

As a result of the patterning of the hydrogen diffusion control layer 131_2, appropriate passivation layer may be formed at an interface between the first insulating layer 120 and the active pattern 112. Consequently, defects in the active pattern 112 may be compensated and may improve the reliability of the driving transistor Tdr1_2. Additionally, the hydrogen diffusion control layer 131_2 may prevent excessive passivation, thereby preventing an increase in a threshold voltage of the driving transistor Tdr1_2.

FIG. 10 is an exemplary cross-sectional view of the hydrogen diffusion control layer shown in FIG. 7. Referring to FIG. 10, the hydrogen diffusion control layer 131 may include a plurality of graphene oxide layers L1, L2, L3. Each of the plurality of oxide layers L1, L2, L3 may include a two-dimensional honeycomb lattice of carbon atoms, with hydrogen compounds attached, providing insulating properties.

Each of the plurality of graphene oxide layers L1, L2, L3 may reduce the space through which hydrogen permeates, thereby decreasing the amount of hydrogen entering the hydrogen diffusion control layer 131. Each of the plurality of graphene oxide layers L1, L2, L3 may also extend the pathway for hydrogen diffusion, allowing the permeated hydrogen to remain longer within the hydrogen diffusion control layer 131. Each of the plurality of graphene oxide layers L1, L2, L3 may bond with hydrogen through sp3 hybridization, and may prevent the escape of hydrogen retained within the hydrogen diffusion control layer 131. According to an embodiment of the present disclosure, each of the plurality of graphene oxide layers L1, L2, L3 may have an oxygen content of 70% or more.

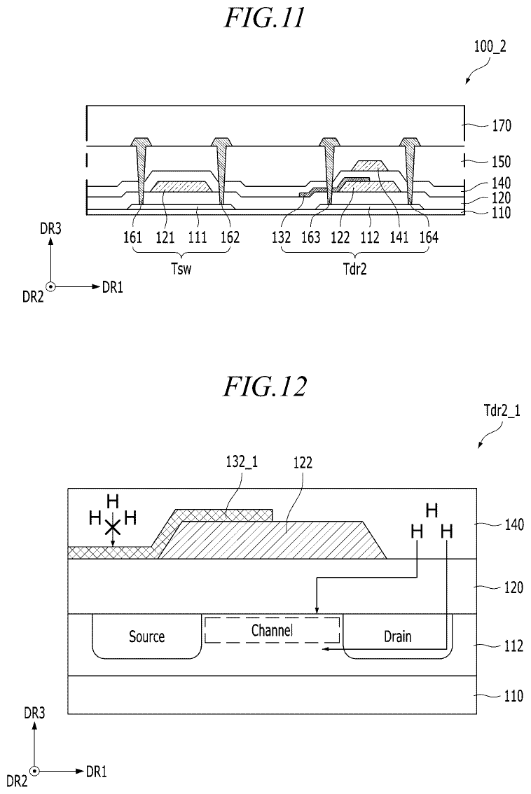

FIG. 11 is a cross-sectional view of a circuit element layer according to an embodiment of the present disclosure. Referring to FIG. 11, a circuit element layer 100_2 may include a buffer layer 110; a semiconductor layer comprising a first active pattern 111, and a second active pattern 112; a first insulating layer 120; a first conductive layer including a first gate pattern 121 and a second gate pattern 122; a hydrogen diffusion control layer 132; a second insulating layer 140; a second conductive layer comprising a third gate pattern 141; a third insulating layer 150; a third conductive layer including a first input pattern 161, a first output pattern 162, a second input pattern 163, and a second output pattern 164; and a planarization layer 170.

Since the circuit element layer 100_2 of FIG. 11 is substantially identical to the circuit element layer 100 shown in FIG. 4 except for the hydrogen diffusion control layer 132, FIG. 11 may be explained based on the hydrogen diffusion control layer 132. The circuit element layer 100_2 may form a switching transistor Tsw and a driving transistor Tdr2. The hydrogen diffusion control layer 132 may overlap a portion of the second active pattern 112 formed in the driving transistor Tdr2.

The hydrogen diffusion control layer 132 may overlap a portion (a source region) that contacts the second input pattern 163 and may not overlap a portion (a drain region) that contact the second output pattern 164. Accordingly, the second input pattern 163 may further penetrate the hydrogen diffusion control layer 132 to contact the second active pattern 112. The second output pattern 164 may contact the second active pattern 112 without penetrating the hydrogen diffusion control layer 132.

FIG. 12 is an exemplary cross-sectional view of the driving transistor of FIG. 11. Referring to FIG. 12, the driving transistor Tdr2 includes a buffer layer 110, an active pattern 112, a first insulating layer 120, a gate pattern 122, a hydrogen diffusion control layer 132_1, and a second insulating layer 140. Compared to FIG. 8, the hydrogen diffusion control layer 132_1 may be patterned to allow hydrogen to diffuse into the portion corresponding to the drain region.

The hydrogen diffusion control layer 132_1 may overlap the source region of the active pattern 112 and may not overlap the drain region of the active pattern 112. As a result, hydrogen diffusion from the second insulating layer 140 to the first insulating layer 120 on the source region may be prevented. Additionally, hydrogen may diffuse from the second insulating layer 140 to the first insulating layer 120 on the drain region, allowing a certain degree of passivation layer to be formed. The source region may be connected to the first driving voltage line VL1 through the fifth transistor T5 illustrated in FIG. 2. The drain region may be connected to the light-emitting element ED through the sixth transistor T6 in FIG. 2.

Passivation of the drain region based on the hydrogen diffusion control layer 132_1 structure in FIG. 11 and FIG. 12 may be more effective in reducing defects in black images than passivation of the source region. As described in FIG. 2, the seventh transistor T7 may be responsible for anode initialization to clearly display black images. Additionally, insufficient passivation of the driving transistor Tdr2 corresponding to the first transistor T1 may result in prominent defects in black images. For example, since the drain region of the driving transistor T1 is connected to the seventh transistor T7 through the sixth transistor T6, passivation of the drain region may effectively reduce defects under conditions where the driving current does not flow.

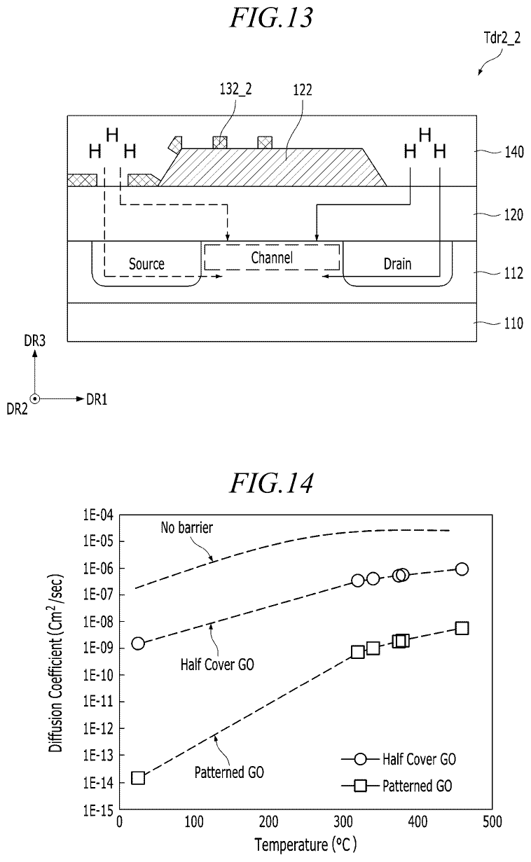

FIG. 13 is an exemplary cross-sectional view of the driving transistor of FIG. 11. Referring to FIG. 13, a driving transistor Tdr2_2 may include a buffer layer 110, an active pattern 112, a first insulating layer 120, a gate pattern 122, a hydrogen diffusion control layer 132_2, and a second insulating layer 140. Compared to FIG. 12, the hydrogen diffusion control layer 132_2 may be patterned to allow at least some hydrogen to diffuse even in the source region.

The hydrogen diffusion control layer 132_2 may overlap with the source region of the active pattern 112. The hydrogen diffusion control layer 131_2 may provide a pattern for the first insulating layer 120 to be in contact with the second insulating layer 140 disposed on the source region of the active pattern 112. Through such patterning, appropriate passivation required for the pixel PX may be achieved.

FIG. 14 is a diagram illustrating an effect of the hydrogen diffusion prevention structure according to an embodiment of the present disclosure. Referring to FIG. 14, the horizontal axis represents temperature, and the vertical axis represents the diffusion coefficient. “No barrier” indicates an embodiment shown in FIG. 5, where no hydrogen diffusion control layer is present. “Half Cover GO” (where GO stands for graphene oxide) represents an embodiment shown in FIG. 12, where the hydrogen diffusion control layer covers the source region and does not cover the drain region. “Patterned GO” represents an embodiment where the hydrogen diffusion control layer is patterned, as shown in FIG. 9. In the absence of a hydrogen diffusion control layer 130, hydrogen diffusion is not controlled, leading to excessive passivation. Therefore, a hydrogen diffusion control layer 130 is required to ensure device performance.

FIG. 15A to FIG. 15G are diagrams illustrating a method for fabricating a circuit element layer according to an embodiment of the present disclosure. A display device according to an embodiment of the present disclosure may be fabricated by forming a circuit element layer disposed on a substrate and forming a light-emitting element layer disposed on the circuit element layer.

Referring to FIG. 15A, a step of forming a circuit element layer 100a may include forming a buffer layer 110 disposed on the substrate SUB and forming a semiconductor layer, which includes a first active pattern 111 and a second active pattern 112, disposed on the buffer layer 110. During this step, doping may be performed to form channels in the first active pattern 111 and the second active pattern 112, and the first active pattern 111 and the second active pattern 112 may be patterned through etching.

Referring to FIG. 15B, a step of forming a circuit element layer 100b may include forming a first insulating layer 120 disposed on a semiconductor layer and forming a first conductive layer, which includes a first gate pattern 121 and a second gate pattern 122. In the step of forming the first insulating layer 120, an insulating layer including silicon oxide may be deposited.

In the step of forming the first conductive layer, the first gate pattern 121 and the second gate pattern 122 may be patterned through etching. The first gate pattern 121 may overlap a first active pattern 111, and the second gate pattern 122 may overlap a second active pattern 112. In the step of forming the first conductive layer, a gate line and a light-emission control line may be formed. Subsequently, doping may be performed to form a source region and a drain region of the first active pattern 111 and the second active pattern 112.

Referring to FIG. 15C, a step of forming a circuit element layer 100c_1 may include forming a hydrogen diffusion control layer 131_2 in patterned form after forming the first conductive layer. The hydrogen diffusion control layer 131_2 corresponds to the hydrogen diffusion control layer 131_2 of FIG. 9. The step of forming the hydrogen diffusion control layer 131_2 may include forming a hydrogen diffusion control layer 131_2 that covers the second active pattern 112 and subsequently patterning the hydrogen diffusion control layer 131_2 that exposes the first insulating layer 120 disposed on the second active pattern 112.

Referring to FIG. 15D, a step of forming a circuit element layer 100c_2 may include forming the hydrogen diffusion control layer 132_1 after forming the first conductive layer. The hydrogen diffusion control layer 132_1 corresponds to the hydrogen diffusion control layer 132_1 of FIG. 12. The step of forming the hydrogen diffusion control layer 132_1 may include forming a hydrogen diffusion control layer 132_1 that covers the second active pattern 112 and subsequently patterning the hydrogen diffusion control layer 132_1 that exposes the first insulating layer 120 disposed on the drain region of the second active pattern 112.

In an embodiment of the present disclosure, prior to forming the hydrogen diffusion control layer 131_2 or 132_1 illustrated in FIG. 15C or FIG. 15D, an additional step of pre-depositing an insulator, including silicon nitride, on the first insulating layer 120 may be included. This additional step may be performed when passivation formation by the hydrogen diffusion control layer 131_2 or 132_1 is determined to be insufficient.

Referring to FIG. 15E, a step of forming a circuit element layer 100d may include forming a second insulating layer 140 on the hydrogen diffusion control layer 130 and the first insulating layer 120 and forming a second conductive layer including the third gate pattern 141 disposed on the second insulating layer 140. In the step of forming the second insulating layer 140, an insulating layer including silicon oxide or silicon nitride may be deposited. When the second insulating layer 140 includes silicon nitride, hydrogen diffusion may occur during a heat treatment process at the time of deposition, and hydrogen diffusion may be controlled by the hydrogen diffusion control layer 130.

In the step of forming the second conductive layer, the third gate pattern 141 may be patterned through etching. The third gate pattern 141 may overlap the second active pattern 112 and the second gate pattern 122. In the step of forming the second conductive layer, a capacitor may be formed by the second gate pattern 122 and the third gate pattern 141.

Referring to FIG. 15F, a step of forming a circuit element layer 100e may include forming the third insulating layer 150, and forming a plurality of contact holes CH1, CH2, CH3, CH4. In the step of forming the third insulating layer 150, an insulating layer including silicon oxide or silicon nitride may be deposited. When the third insulating layer 150 includes silicon nitride, hydrogen diffusion may occur during a heat treatment process of deposition, and hydrogen diffusion may be controlled by the hydrogen diffusion control layer 130.

The plurality of contact holes CH1, CH2, CH3, CH4 may be provided to form first input pattern 161, second input pattern 163, first output pattern 162, and second output pattern 164 as explained below. The plurality of contact holes CH1, CH2, CH3, CH4 may be patterned to penetrate the first to the third insulating layers 120, 140, 150 by etching.

Referring to FIG. 15G, a step of forming a circuit element layer 100f may include a forming of a third conductive layer including the first input pattern 161, the first output pattern 162, the second input pattern 163, and the second output pattern 164. The third conductive layer, which includes the first input pattern 161, the first output pattern 162, the second input pattern 163, and the second output pattern 164, may be disposed on the third insulating layer 150 and may be in contact with the semiconductor layer via the plurality of contact holes CH1, CH2, CH3, CH4. Although not illustrated, of the step of forming the circuit element layer 100f may further include a step of forming the planarization layer 170 after the forming of a third conductive layer.

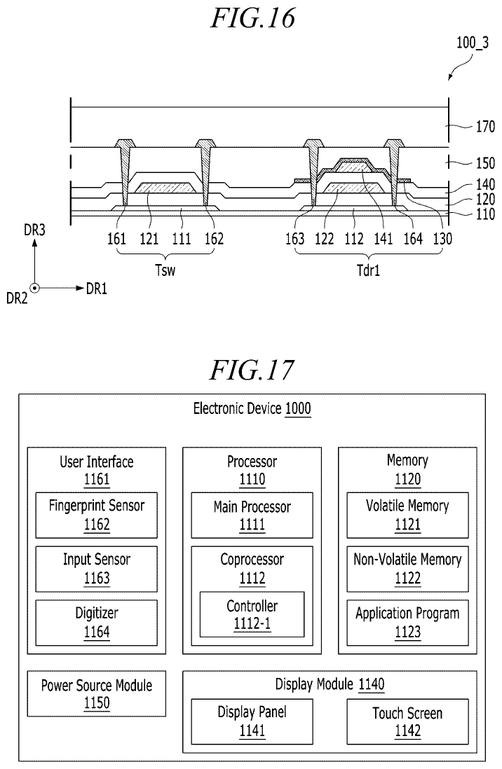

FIG. 16 is a cross-sectional view of a circuit element layer according to an embodiment of the present disclosure. Referring to FIG. 16, a circuit element layer 100_3 may include the buffer layer 110; the semiconductor layer including the first active pattern 111, and the second active pattern 112; the first insulating layer 120; the first conductive layer including the first gate pattern 121 and the second gate pattern 122; the hydrogen diffusion control layer 131; the second insulating layer 140; the second conductive layer including the third gate pattern 141; the third insulating layer 150; the third conductive layer including the first input pattern 161, the first output pattern 162, the second input pattern 163 and the second output pattern 164; and the planarization layer 170.

The circuit element layer 100_3 of FIG. 16 may be substantially identical to the circuit element layer 100 illustrated in FIG. 4, except for the hydrogen diffusion control layer 130. The hydrogen diffusion control layer 130 may also be disposed between the second insulating layer 140 and the third insulating layer 150. In this case, the first insulating layer 120 and the second insulating layer 140 may include silicon oxide, while the third insulating layer 150 may include silicon nitride. For example, the hydrogen diffusion control layer 130 may be formed before the hydrogen diffusion occurs. A shape of the hydrogen diffusion control layer 130 may have the previously described pattern.

Moreover, the hydrogen diffusion control layer 130 may also be disposed between the first insulating layer 120 and the second insulating layer 140, or between the second insulating layer 140 and the third insulating layer 150. Furthermore, the hydrogen diffusion control layer 130 may cover the switching transistor Tsw while configured to have the aforementioned pattern.

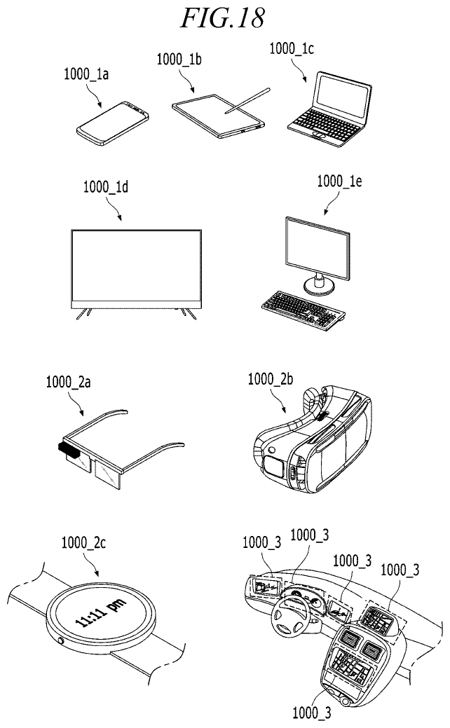

FIG. 17 is a block diagram showing an electronic device according to embodiments of the present disclosure. Referring to FIG. 17, the electronic device 1000 according to one embodiment of the present invention may output various information (e.g., images, text, music, etc.) through a display module 1140, which, for example, may correspond to the display device shown in FIG. 1. When a processor 1110 executes an application stored in a memory 1120, the display module 1140 may provide application information to a user through a display panel 1141.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 be an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device shown in FIG. 1.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display unit shown in FIG. 1.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

FIG. 18 illustrates schematic diagrams of electronic devices according to one or more embodiments.

Referring to FIG. 18, one or more suitable electronic devices having display devices according to one or more embodiments may include not only an image display electronic device, such as a smart phone 1000-1a, a tablet PC 1000-1b, a laptop 1000-1c, a TV 1000-1d, and a desk monitor 1000-1e, but also a wearable electronic device including a display module, such as a smart glass 1000-2a, a head mounted display 1000-2b, and/or a smart watch 1000-2c, and/or a vehicle electronic device 1000-3 including a display module, such as a Center Information Display (CID) and/or a room mirror display on an instrument panel, center fascia, and/or a dashboard of an automobile.

Albeit described with reference to the embodiments above, anyone ordinarily skilled in the art to which the present disclosure pertains shall appreciate that there may be a variety of modifications and permutations of the present disclosure without departing from the technical ideas and scopes of the present disclosure that are defined in the appended claims. Moreover, it shall be appreciated that the disclosed embodiments are not intended to restrict the present disclosure thereto and that every technical idea within the appended claims and their equivalents is interpreted to be included in the scope of the present disclosure.

What is claimed is:

1. A display device comprising:
a substrate;
a light-emitting element layer disposed on the substrate and comprising a light-emitting material; and
a circuit element layer disposed between the substrate and the light-emitting element layer and having a first region that corresponds to a switching transistor and a second region that corresponds to a driving transistor,
wherein the circuit element layer comprises:
a semiconductor layer disposed on the substrate and comprising a first active pattern that overlaps the first region and a second active pattern that overlaps the second region;
a first conductive layer disposed on the semiconductor layer and comprising a first gate pattern that overlaps the first region and a second gate pattern that overlaps the second region;
a first insulating layer disposed between the semiconductor layer and the first conductive layer;
a second insulating layer disposed on the first conductive layer;
a second conductive layer disposed on the second insulating layer and is in contact with the semiconductor layer by penetrating the first insulating layer and the second insulating layer,
wherein the second conductive layer comprises a first input pattern and a first output pattern that contacts the first active pattern, and a second input pattern and a second output pattern that contacts the second active pattern; and
a hydrogen diffusion control layer disposed between the first insulating layer and the second insulating layer, and overlapping the second region;
wherein the second active pattern comprises a first portion and a second portion that are spaced apart from each other, and
wherein the hydrogen diffusion control layer covers the first portion of the second active pattern and at least a portion of the second portion does not overlap the hydrogen diffusion control layer.

2. The display device of claim 1,
wherein the second input pattern penetrates the hydrogen diffusion control layer to contact the first portion of the second active pattern, and
wherein the second output pattern does not penetrate the hydrogen diffusion control layer to contact the second portion of the second active pattern.

3. The display device of claim 2,
wherein the second conductive layer further comprises a driving voltage line that transfers a driving voltage to the circuit element layer, and
wherein the driving voltage line is disposed closer to the second input pattern than to the second output pattern.

4. The display device of claim 2,
wherein a light-emitting element layer further comprises an electrode layer, having a contact pattern that contacts the second conductive layer, and
wherein the contact pattern is disposed closer to the second output pattern than to the second input pattern.

5. The display device of claim 1,
wherein an area of the hydrogen diffusion control layer is larger than an area of the first portion of the second active pattern.

6. The display device of claim 1,
wherein the hydrogen diffusion control layer further covers at least a portion of the second gate pattern.

7. The display device of claim 1,
wherein the circuit element layer further comprises:
a third conductive layer disposed between the first insulating layer and the second insulating layer and comprising a third gate pattern overlapping the second gate pattern; and
a third insulating layer disposed between the first insulating layer and the second insulating layer and between the second gate pattern and the third gate pattern,
wherein the hydrogen diffusion control layer is disposed between the third insulating layer and the first insulating layer.

8. A display device comprising:
a substrate;
a light-emitting element layer disposed on the substrate and comprising a light-emitting material; and
a circuit element layer disposed between the substrate and the light-emitting element layer and having a first region that corresponds to a switching transistor and a second region that corresponds to a driving transistor,
wherein the circuit element layer comprises:
a semiconductor layer disposed on the substrate and comprising a first active pattern that overlaps the first region and a second active pattern that overlaps the second region;
a first conductive layer disposed on the substrate and comprising a first gate pattern that overlaps the first region and a second gate pattern that overlaps the second region;
a first insulating layer disposed between the semiconductor layer and the first conductive layer;
a second insulating layer disposed on the first conductive layer;
a second conductive layer disposed on the second insulating layer and is in contact with the semiconductor layer by penetrating the first insulating layer and the second insulating layer; and
a hydrogen diffusion control layer disposed between the first insulating layer and the second insulating layer, overlapping the second active pattern, and includes a pattern that allows the first insulating layer to contact the second insulating layer.

9. The display device of claim 8,
wherein the hydrogen diffusion control layer comprises a graphene oxide layer.

10. The display device of claim 9,
wherein the graphene oxide layer comprises a plurality of layers stacked between the first insulating layer and the second insulating layer.

11. The display device of claim 8,
wherein the second insulating layer has a higher hydrogen content than the first insulating layer.

12. The display device of claim 11,
wherein the first insulating layer comprises silicon oxide, and the second insulating layer comprises silicon nitride.

13. The display device of claim 8,
wherein the second active pattern comprises a first portion and a second portion that are spaced apart from each other, and
wherein the hydrogen diffusion control layer covers the first portion and the second portion.

14. The display device of claim 13,
wherein the second active pattern overlaps the second gate pattern.

15. The display device of claim 8,
wherein the circuit element layer further comprises:
a third conductive layer disposed on the second insulating layer and comprising a third gate pattern that overlaps the second gate pattern; and
a third insulating layer disposed on the first insulating layer and the second insulating layer and between the second gate pattern and the third gate pattern.

16. An electronic device, comprising:
a processor;
a memory having stored application programs for execution by the processor;
a display device, comprising:
a display panel comprising:
a substrate;
a light-emitting element layer disposed on the substrate and comprising a light-emitting material; and
a circuit element layer disposed between the substrate and the light-emitting element layer and having a first region that corresponds to a switching transistor and a second region that corresponds to a driving transistor,
wherein the circuit element layer comprises:
a semiconductor layer disposed on the substrate and comprising a first active pattern that overlaps the first region and a second active pattern that overlaps the second region;
a first conductive layer disposed on the semiconductor layer and comprising a first gate pattern that overlaps the first region and a second gate pattern that overlaps the second region;
a first insulating layer disposed between the semiconductor layer and the first conductive layer;
a second insulating layer disposed on the first conductive layer;
a second conductive layer disposed on the second insulating layer and is in contact with the semiconductor layer by penetrating the first insulating layer and the second insulating layer,
wherein the second conductive layer comprises a first input pattern and a first output pattern that contacts the first active pattern, and a second input pattern and a second output pattern that contacts the second active pattern; and
a hydrogen diffusion control layer disposed between the first insulating layer and the second insulating layer, and overlapping the second region;
wherein the second active pattern comprises a first portion and a second portion that are spaced apart from each other, and
wherein the hydrogen diffusion control layer covers the first portion of the second active pattern and at least a portion of the second portion does not overlap the hydrogen diffusion control layer; and
a user interface configured to sense user input via touch or cursor select of an icon presented on the display panel, wherein the processor is caused to execute one or more of the stored application programs upon receipt of the user input.

17. The electronic device of claim 16, wherein the stored application programs include one or more of a camera application, an audiovisual streaming application, or a telephone application.

18. The electronic device of claim 16, wherein the user interface is a touch screen embedded in the display panel, wherein the touch screen includes touch sensors for sensing a touch or a tap by a user.

19. The electronic device of claim 16, wherein the user interface includes an audio sensor embedded in the display panel, wherein the audio sensor is configured to receive voice commands to cause access to one or more of the application programs.

20. The electronic device of claim 16, wherein the user interface includes sensors for sensing eye movements installed in the display panel.
